(19) United States
(12) Patent Application Publication
(10) Pub. No.: US 2013/0241211 A1
(43) Pub. Date: Sep. 19, 2013

(54) POWER GENERATOR, ELECTRONIC DEVICE, AND POWER GENERATING DEVICE

(71) Applicant: NIKON CORPORATION, Tokyo (JP)

(72) Inventor: Takeshi YAGI, Tokyo (JP)

(73) Assignee: NIKON CORPORATION, Tokyo (JP)

(21) Appl. No.: 13/890,626

(22) Filed: May 9, 2013

Related U.S. Application Data
(63) Continuation of application No. PCT/JP2012/050342, filed on Jan. 11, 2012.

(30) Foreign Application Priority Data
Jan. 12, 2011 (JP) 2011-003966
Dec. 15, 2011 (JP) 2011-274324
Jan. 4, 2012 (JP) 2012-000181

(51) Int. Cl. F03G 1/00

(52) U.S. Cl. CPC F03G 1/00
USPC 290/1 E

(57) ABSTRACT

An electronic device includes a power generator, a power supply unit (secondary battery) which stores power generated by the power generator, and a processing unit (load circuit) which is driven with power supplied from the power supply unit. The power generator includes a spring, a power-generating unit which is formed using a magnetostrictive material, and a capacitor. The spring stores force by vibration, operation of an operator, or wind power. The power-generating unit generates power by force stored in the spring when force is not applied to the magnetostrictive material.

### CROSS-REFERENCE TO RELATED APPLICATION

This is a Continuation application of International Application No. PCT/JP20121050342, filed Jan. 11, 2012, which claims priority to Japanese Patent Application No. 2011-003966, filed on Jan. 12, 2011, Japanese Patent Application No. 2011-274324, filed on Dec. 15, 2011, and Japanese Patent Application No. 2012-000181, filed on Jan. 4, 2012. The contents of the aforementioned applications are incorporated herein by reference.

### BACKGROUND

1. Field of the Invention

The present invention relates to a power generator, an electronic device, and a power-generating device.

2. Description of Related Art

In the related art, a technique is known in which a piezoelectric material is deflected to generate power (for example, see Japanese Unexamined Patent Application, First Publication No. 2010-230440).

As a piezoelectric body of the power-generating device, for example, ceramics formed in a rod shape is used.

### SUMMARY

However, in the technique disclosed in Japanese Unexamined Patent Application, First Publication No. 2010-230440, there is a problem in that power generation is not possible when the piezoelectric material is not vibrating. Since ceramics, which is one of the piezoelectric materials, has high impedance, there is a problem in that a small amount of power is obtained. Furthermore, since ceramics is a brittle material, there is a problem in that it is not suitable for reduction in size.

An aspect of the invention provides a technique which generates power by vibration, continuously generates power even when there is no vibration, obtains a large amount of power, and is suitable for reduction in size.

When a piezoelectric body is formed in a rod shape, there is a problem in that it is not suitable for reduction in size in one direction. That is, ceramics is a brittle material and thus vulnerable to impact or the like, and there is a problem in that it is difficult to produce a complicated shape, such as a coil shape, so as to increase the amount of deflection with a limited volume and to increase the amount of power generation.

Another aspect of the invention provides a power-generating device and an electronic device suitable for reduction in size.

A power generator according to a first aspect of the invention includes a spring, and a power-generating unit which is formed using a magnetostrictive material, wherein the power-generating unit generates power by force stored in the spring when force is not applied to the magnetostrictive material.

In the power generator, the spring may store force by vibration, operation of an operator, or wind power.

An electronic device according to another aspect of the invention includes the above-described power generator.

A second aspect of the invention provides a power-generating device including a vibrating portion which is formed to have a spiral shape in one direction and includes a magnetostrictive material, a vibration transmission portion which transmits vibration to the vibrating portion, and a coil portion which generates an induced current according to change in magnetic flux density caused by the vibration of the vibrating portion.

Another aspect of the invention provides an electronic device including a processing unit which performs predetermined processing, a power supply unit which supplies power to the processing unit, and a power-generating unit which generates at least a part of the power to be supplied from the power supply unit to the processing unit, wherein the power-generating device according to the first aspect of the invention is used as the power-generating unit.

According to the aspect of the invention, continuous power generation becomes possible even when a housing is not vibrating. For example, it is possible to obtain a large amount of power compared to a piezoelectric element, and it is more robust and more suitable for reduction in size.

According to another aspect of the invention, it is possible to provide a power-generating device and an electronic device suitable for reduction in size.

### BRIEF DESCRIPTION OF THE DRAWINGS

FIG. 1A is a configuration diagram of an electronic device according to a first embodiment of the invention.

FIG. 1B is a configuration diagram of the electronic device according to the first embodiment of the invention.

FIG. 2 is a schematic view of a power-generating unit according to the first embodiment of the invention.

FIG. 3A is a schematic view of a power-generating unit according to the first embodiment of the invention.

FIG. 3B is a schematic view of the power-generating unit according to the first embodiment of the invention.

FIG. 4 is a block diagram showing the schematic configuration of an electronic device according to a second embodiment of the invention.

FIG. 5 is a schematic perspective view showing the configuration of a power-generating unit according to the second embodiment of the invention.

FIG. 6 is a diagram showing the configuration of a part of the power-generating unit according to the second embodiment of the invention.

FIG. 7 is a diagram showing another configuration of the power-generating unit according to the second embodiment of the invention.

FIG. 8 is a diagram showing another configuration of the power-generating unit according to the second embodiment of the invention.

### DESCRIPTION OF EMBODIMENTS

### First Embodiment

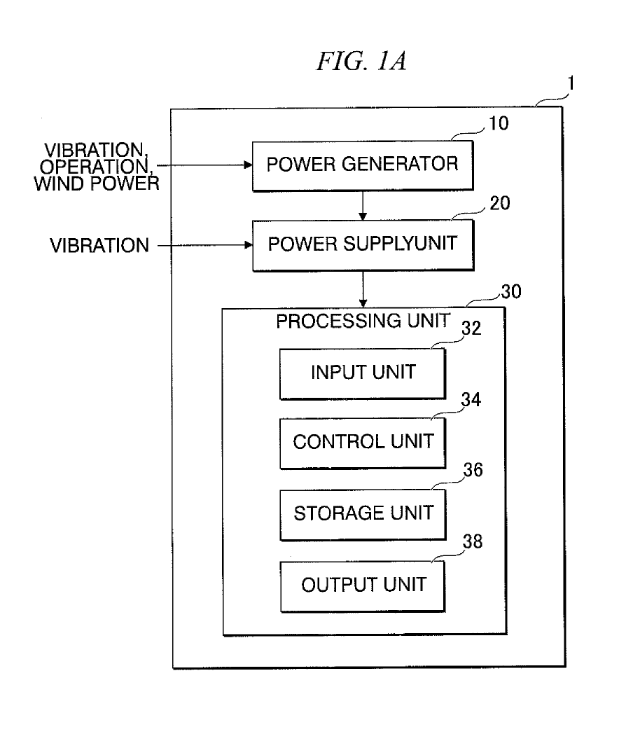

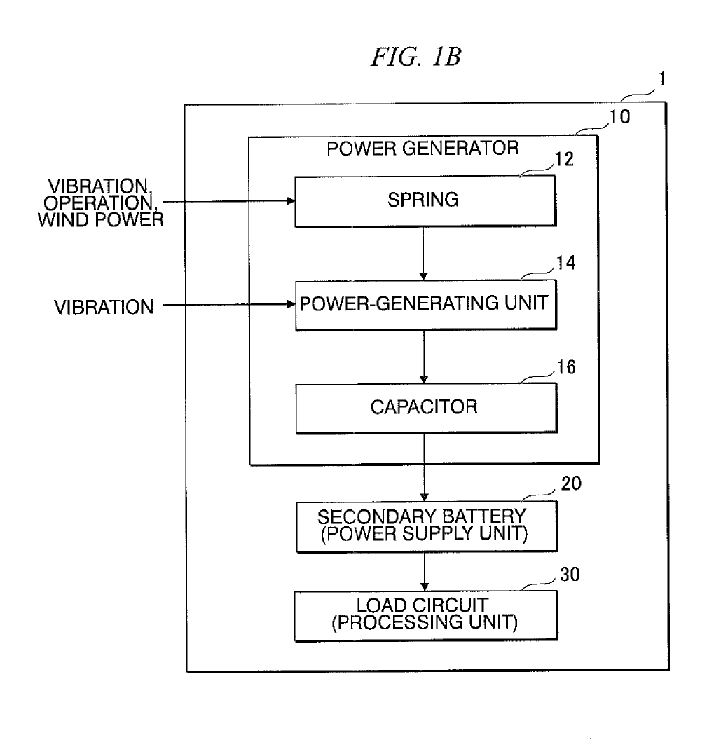

Hereinafter, a first embodiment of the invention will be described referring to the drawings. FIG. 1A is a schematic functional configuration diagram of an electronic device 1 according to the first embodiment of the invention. FIG. 1B is a detailed configuration diagram of a power generator 10 shown in FIG. 1A. FIG. 2 is a schematic view of a power-generating unit 14.

An electronic device 1 is, for example, a portable information device, and as shown in FIG. 1A, includes a power generator 10, a power supply unit (secondary battery) 20 which stores power generated by the power generator 10, and a processing unit (load circuit) 30 which is driven with power supplied from the power supply unit 20.

The processing unit 30 includes an input unit 32, a control unit 34, a storage unit 36, and an output unit 38. The input unit 32 inputs information from the outside. While the input unit 32 differs depending on the type of the electronic device 1, for example, a receiving unit which receives information transmitted from the outside, an operation-receiving unit which receives an input operation by an operator, a detection unit (for example, a magnetic sensor) which detects an external environment, or the like corresponds to the input unit 32.

The control unit 34 performs various kinds of processing based on information input by the input unit 32, information stored in the storage unit 36, or the like. The storage unit 36 stores information input by the input unit 32, information (for example, a control program) which is used for processing by the control unit 34, information (for example, output information) generated by the control unit 34, or the like.

The output unit 38 outputs information to the outside. While the output unit 38 differs depending on the type of the electronic device 1, for example, a transmitting unit which transmits information to the outside, a presentation unit (for example, a display, a lamp, or a speaker) which presents information to the operator, a driving unit which drives (for example, a vibration function) the housing (hereinafter, referred to as a “housing”) of the electronic device 1, or the like corresponds to the output unit 38.

The power generator 10 includes at least a spring 12 and the power-generating unit 14, and as shown in FIG. 1B, may include a capacitor 16 in addition to the spring 12 and the power-generating unit 14.

The spring 12 stores force (elastic energy) by the vibration of the housing. For example, the spring 12 stores force by vibration when the user consciously shakes the housing, vibration when a user carries the housing, driving (for example, a vibration function) by processing of the processing unit 30, or the like.

The spring 12 may store force from other than vibration. For example, the spring 12 may store force by operation of the operator, wind power, or the like. When wind power is used, a windmill (fan) may be used.

As the operation of the operator, an operation to directly store force in the spring 12 (for example, an operation to consciously wind up the spring), or an operation to indirectly store force in the spring 12 may be used. An example of the operation to indirectly store force in the spring 12 is an operation to hold down a button arranged in the housing. That is, the spring 12 stores force when a button is held down.

Force stored in the spring 12 is used as force which deforms (vibrates, deflects) the magnetostrictive material of the power-generating unit 14 (details will be described below).

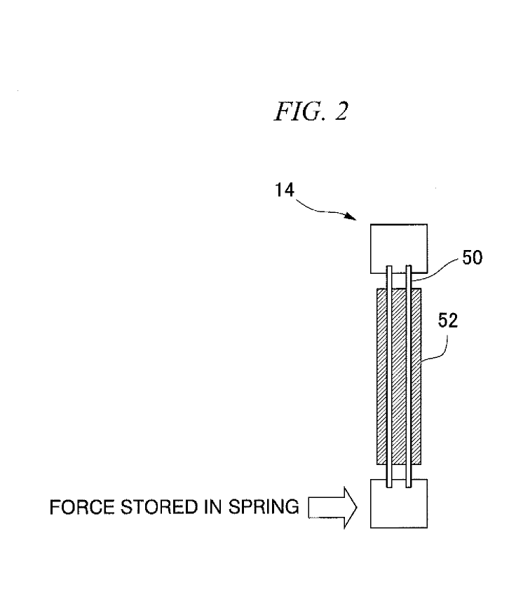

As shown in FIG. 2, the power-generating unit 14 has magnetostrictive materials 50 and a coil 52. FIG. 2 is a sectional view in which the magnetostrictive materials 50 in the coil 52 are shown. In FIG. 2, although two magnetostrictive materials 50 are shown, the power-generating unit 14 may have one or three or more magnetostrictive materials 50 (the same applies to a power-generating unit 114 of FIG. 3 described below). Although FIG. 2 shows the coil 52 wound around the two magnetostrictive materials 50 together, as a way of winding the coil 52, the coil 52 may be wound around each magnetostrictive material 50.

The magnetostrictive materials 50 of the power-generating unit 14 are deformed by force (bending force, pulling force, stretching force), and cause change in magnetic flux density (inverse magnetostriction effect). The coil 52 of the power-generating unit 14 generates an induced current according to change in magnetic flux density. That is, when force is applied to the magnetostrictive materials 50 (that is, when vibration or deflection is given), the power-generating unit 14 changes force to be applied to the magnetostrictive materials 50 to electricity, that is, generates power (obtains electric energy). For example, the power-generating unit 14 generates power when force is applied to the magnetostrictive materials 50 by the vibration of the housing.

When the magnetostrictive materials 50 are used, for example, the following effects can be obtained. As the magnetostrictive materials 50, a Fe—Ga-based material (iron-gallium alloy) is preferably used.
While a small amount of power is obtained by a load in a piezoelectric element which has capacitive impedance (high impedance), since the magnetostrictive materials 50 have low impedance, a large amount of power is obtained by a load (matching with the load is satisfactory).
While a piezoelectric element using ceramics (brittle material) is unsuitable for processing, since the magnetostrictive materials 50 are hard to break and are ductile, mechanical processing is possible. Accordingly, since extreme reduction in size (above several millimeters) is possible, it is useful for mounting in a compact electronic device (for example, a portable music player, a mobile communication device, or a human body-implantable medical device).
The magnetostrictive materials 50 have the amount of power generation proportional to the size of the material.
While a piezoelectric element has low efficiency (piezoelectric transverse effect), the magnetostrictive materials 50 have high efficiency.
Power generation by resonant vibration is obtained.
A wide temperature use range (−100° C. to 100° C.) is provided.

When the housing is vibrating, as described above, the magnetostrictive materials 50 of the power-generating unit 14 are deformed by the vibration to generate power. However, even when the housing is not vibrating, the magnetostrictive materials 50 are deformed by force stored in the spring 12 to generate power. For example, as shown in FIG. 2, when the magnetostrictive materials 50 are formed in a plate shape (or a rod shape), force stored in the spring 12 may be transmitted in a direction (an arrow direction of FIG. 2), in which the magnetostrictive materials 50 are deflected, to cause the power-generating unit 14 to generate power. An opposite side (an upper side of FIG. 2) of a portion (an arrow portion of FIG. 2) to which force stored in the spring 12 is transmitted is fixed, and if force stored in the spring 12 is transmitted, the magnetostrictive materials 50 are deflected.

Force stored in the spring 12 may be transmitted in a direction in which the magnetostrictive materials 50 expand and contract in a longitudinal direction to cause the power-generating unit 14 to generate power.

The power-generating unit 14 supplies the generated power (power by the vibration of the housing or power by force stored in the spring 12) to the secondary battery 20 through the capacitor 16. The capacitor 16 is used so as to stabilize power supplied to the secondary battery 20.

With the electronic device 1 according to the first embodiment of the invention, when the housing is vibrating, the power-generating unit 14 generates power using the vibration of the housing, and the spring 12 stores force. When the housing is not vibrating, the power-generating unit 14 generates power using force stored in the spring 12. Therefore, continuous power generation becomes possible even when the housing is not vibrating.

When power generation is carried out using the magnetostrictive materials 50, as described above, a large amount of power can be obtained compared to a piezoelectric element, and it is more robust and more suitable for reduction in size. As described above, with the characteristics of the magnetostrictive materials 50 or since vibration energy of the housing is changed to electric energy in the magnetostrictive materials 50, and is also retained in the spring 12 as elastic energy, high-efficiency power generation becomes possible. A stable amount of power generation can also be obtained regardless of the magnitude of vibration.

In the configuration of the power-generating unit 14 shown in FIG. 2, if the vibration of the magnetostrictive materials 50 is resonant vibration, the efficiency of power generation is improved. Hereinafter, a configuration in which a resonance frequency can be changed will be described.

FIGS. 3A and 3B are schematic views of a power-generating unit 114. FIG. 3A is a sectional view in which the magnetostrictive materials 50 in the coil 52 are shown, and FIG. 3B is a sectional view showing a section along the broken line S of FIG. 3A. FIGS. 3A and 3B respectively show the coil 52 wound around the two magnetostrictive materials 50 together and the coil 52 wound around each magnetostrictive material 50.

The power generator 10 may include the power-generating unit 114 shown in FIG. 3A instead of the power-generating unit 14 shown in FIG. 2. The power-generating unit 114 has magnetostrictive materials 50, a coil 52, and a movable portion (weight) 54. The movable portion 54 is movable in the longitudinal direction (an arrow A direction of FIG. 3A) of the magnetostrictive materials 50. The distance between the fixed portion 55 and the movable portion 54 changes with the movement of the movable portion 54.

In the configuration of the power-generating unit 114 shown in FIG. 3A, since the position of the movable portion 54 changes, and the distance between the fixed portion 55 and the movable portion 54 changes, the resonance frequency can be changed. That is, if the distance between the fixed portion 55 and the movable portion 54 is shortened, the resonance frequency increases, and if the distance between the fixed portion 55 and the movable portion 54 is extended, the resonance frequency decreases.

As a method of changing (method of adjusting) the position of the movable portion 54 (the distance between the fixed portion 55 and the movable portion 54), a few methods are considered. For example, an actuator (not shown) is arranged outside the movable portion 54, and the actuator applies force to the movable portion 54 such that the movable portion 54 moves in the longitudinal direction of the magnetostrictive materials 50 to change the position of the movable portion 54. An actuator (not shown) may be arranged inside the movable portion 54, and the movable portion 54 may be self-propelled by the driving of the actuator to change the position of the movable portion 54.

The optimum resonance frequency may be determined from the position of the movable portion 54 at which the amount of generated power is maximal in a state where the housing is vibrating. When the housing is not vibrating, the movable portion 54 is moved using force stored in the spring 12 in a direction (an arrow B direction of FIG. 3A) in which the magnetostrictive materials 50 are deflected, and the magnetostrictive materials 50 are deformed to perform power generation.

Although the first embodiment of the invention has been described in detail referring to the drawings, a specific configuration is not limited to the embodiment, and changes may be appropriately made without departing from the scope of the invention

### Second Embodiment

Hereinafter, a second embodiment of the invention will be described referring to the drawings.

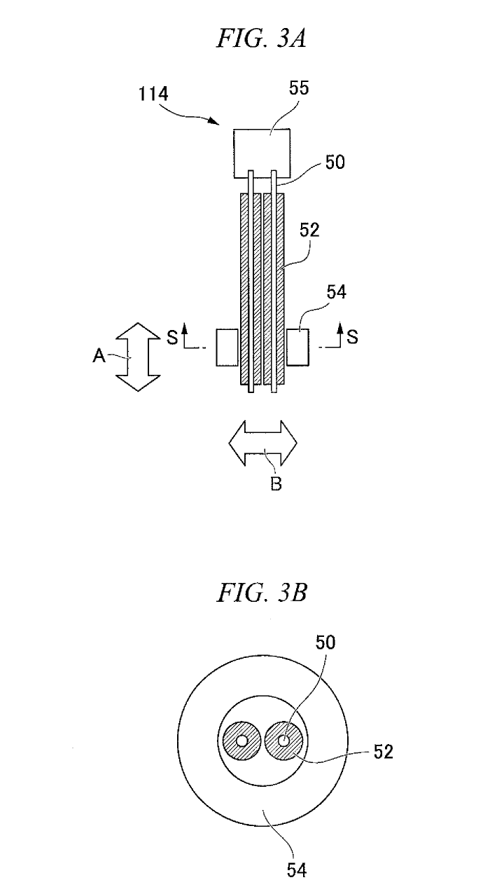

FIG. 4 is a schematic functional configuration diagram of an electronic device 2 according to a second embodiment of the invention. As shown in FIG. 4, the electronic device 2 has a processing unit 230 which performs predetermined processing, a power supply unit 220 which supplies power to the processing unit 230, and a power-generating unit 210 which generates at least a part of power supplied from the power supply unit 220 to the processing unit 230. As the electronic device 2, a portable information terminal or the like which is formed of a portable size is provided.

The processing unit 230 includes an input unit 232, a control unit 234, a storage unit 236, and an output unit 238. The input unit 232 inputs information from the outside. While the input unit 232 differs depending on the type of the electronic device 2, for example, a receiving unit which receives information transmitted from the outside, an operation-receiving unit which receives an input operation by an operator, a detection unit (for example, a magnetic sensor) which detects an external environment, or the like corresponds to the input unit 232.

The control unit 234 performs various kinds of processing based on information input by the input unit 232, information stored in the storage unit 236, or the like. The storage unit 236 stores information input by the input unit 232, information (for example, a control program) which is used for processing by the control unit 234, information (for example, output information) generated by the control unit 234, or the like.

The output unit 238 outputs information to the outside. While the output unit 238 differs depending on the type of the electronic device 2, for example, a transmitting unit which transmits information to the outside, a presentation unit (for example, a display, a lamp, or a speaker) which presents information to the operator, a driving unit which drives (for example, a vibration function) the housing (hereinafter, referred to as a “housing”) of the electronic device 2, or the like corresponds to the output unit 238.

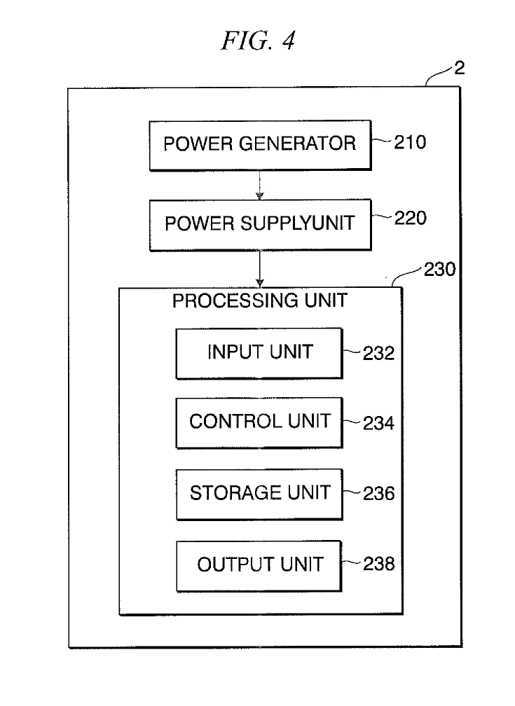

FIG. 5 is a perspective view showing the configuration of the power-generating unit 210.

As shown in FIG. 5, the power-generating unit 210 has a frame portion 211, a vibrating portion 212, a vibration transmission portion 213, and a coil portion 214. The power-generating unit 210 has a configuration in which the vibrating portion 212 and the vibration transmission portion 213 are integrally supported by the frame portion 211. The frame portion 211 is fixed to the housing or the like of the electronic device 2.

The vibrating portion 212 has a linear member 212e including a magnetostrictive material. The vibrating portion 212 has a configuration in which the linear member 212c is wound in a spiral shape (spring shape) in a predetermined direction. For this reason, the vibrating portion 212 is configured to expand and contract in the predetermined direction. Specifically, the vibrating portion 212 is deformed by force (bending force, pulling force, stretching force, or the like) from the outside, and expands and contracts in a predetermined direction.

As the magnetostrictive materials, for example, a Fe—Ga-based material (iron-gallium alloy) is used.

Since the vibrating portion 212 includes the magnetostrictive material, the vibrating portion 212 has a function of causing change in surrounding magnetic flux density when deformed (inverse magnetostriction effect).

A first end portion (an upper end portion in the drawing) 212a of the vibrating portion 212 in one direction is fixed to a fixed portion 211a of the frame portion 211. The fixed portion 211a is provided to protrude from the frame portion 211. An opposite second end portion 212b of the vibrating portion 212 in one direction is connected to a movable portion 213b of the vibration transmission portion 213.

The vibration transmission portion 213 has a weight body 213a and a movable portion 213b. The vibration transmission portion 213 transmits vibration to the vibrating portion 212. The weight body 213a is connected to the second end portion 212b of the vibrating portion 212 through the movable portion 213b. The movable portion 213b is configured such that one end portion 213c is supported by the frame portion 211, and the other end portion 213d is rotatable around the end portion 213c supported by the frame portion 211.

The weight body 213a is arranged at the other end of the movable portion 213b. The second end portion 212b of the vibrating portion 212 is connected between the end portion 213c and the end portion 213d of the movable portion 213b.

When the electronic device 2 vibrates, the weight body 213a makes it easy to transmit the vibration of the electronic device 2 to the vibrating portion 212 on a leverage principle. Examples of the vibration of the electronic device 2 include vibration when the user intentionally shakes the electronic device 2, vibration when the user carries the electronic device 2, driving (for example, a vibration function) by processing of the processing unit 230, and the like.

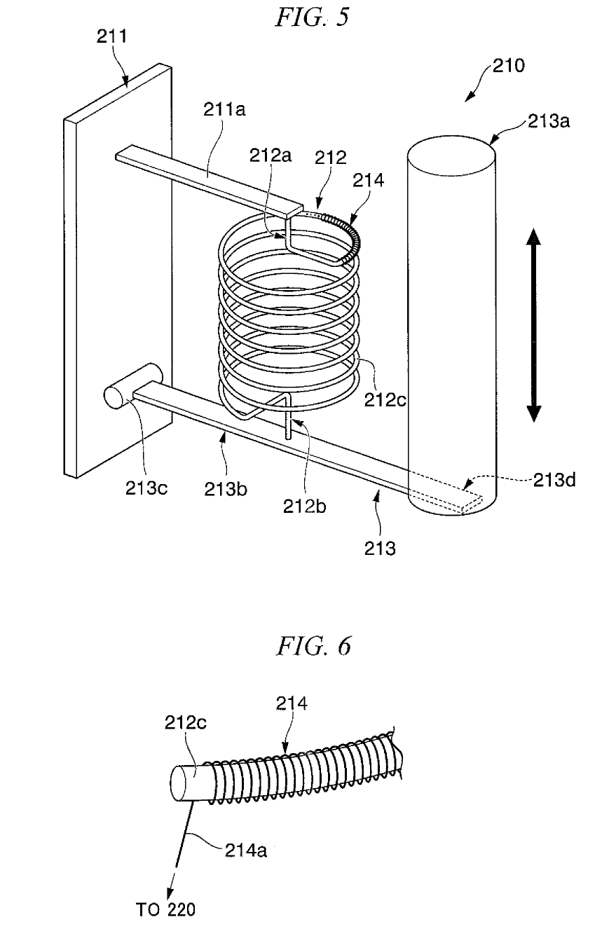

The coil portion 214 generates an induced current according to change in magnetic flux density caused by the vibration of the vibrating portion 212. FIG. 6 is a diagram showing a part of the vibrating portion 212 on a magnified scale. As shown in FIG. 6, the coil portion 214 has a configuration in which an electric wire 214a is wound around the linear member of the vibrating portion 212. As the configuration of the coil portion 214, in addition to the configuration in which the electric wire 214a is directly wound around the linear member of the vibrating portion 212, for example, a configuration in which the linear member of the vibrating portion 212 is formed so as to be covered with a tube member, and an electric wire is formed on the tube member may be made. The electric wire 214a of the coil portion 214 is connected to the power supply unit 220.

Next, an operation when power generation is performed using the electronic device 2 configured as described above will be described. While the user holds the electronic device 2, the electronic device 2 receives force, impact, or the like from the user. At this time, the weight body 213a vibrates by force, impact, or the like. If the weight body 213a vibrates, the vibration is transmitted to the movable portion 213b. The movable portion 213b vibrates in a rotation direction around the end portion 213c supported by the frame portion 211. The vibration of the movable portion 213b is transmitted to the vibrating portion 212 through the second end portion 212b. In this way, the movable portion 213b vibrates with the weight body 213a on the leverage principle, whereby the vibration which is transmitted to the vibrating portion 212 increases compared to a case where the weight body 213a is not provided.

If the vibration from the movable portion 213b is transmitted, the vibrating portion 212 expands and contracts in a predetermined direction. Since the vibrating portion 212 includes the magnetostrictive material, magnetic flux density around the vibrating portion 212 changes due to deformation at the time of the expansion and contraction of the vibrating portion 212. If change in magnetic flux density occurs, in the coil portion 214, an induced current based on change in magnetic flux density is generated. In this way, the power generation operation in the power-generating unit 210 is performed.

The induced current generated in the coil portion 214 is supplied to the power supply unit 220 through the electric wire 214a. A capacitor (not shown) may be provided between the coil portion 214 and the power supply unit 220. The capacitor is used so as to stabilize power supplied to the power supply unit 220. In this way, power is stored in the power supply unit 220 by the induced current supplied from the power-generating unit 210.

As described above, according to this embodiment, the vibrating portion 212 which is formed to have a spiral shape in a predetermined direction and includes a magnetostrictive material, the vibration transmission portion 213 which transmits vibration to the vibrating portion 212, and the coil portion 214 which generates an induced current according to change in magnetic flux density caused by the vibration of the vibrating portion 212 are provided, whereby reduction in size becomes possible compared to a configuration in which power generation is carried out using a piezoelectric material, for example.

That is, for example, a piezoelectric material, such as ceramics, is a brittle material and is thus unsuitable for processing. In contrast, since the magnetostrictive materials are hard to break and are ductile, mechanical processing is possible. Accordingly, since extreme reduction in size (about several millimeters) is possible, it is useful for mounting in a compact electronic device (for example, a portable music player, a mobile communication device, or a human body-implantable medical device).

In this embodiment, since a magnetostrictive material is included in the vibrating portion 212, for example, power to be obtained increases compared to a case where a piezoelectric element (piezoelectric material) is deformed to generate a current. This is because the piezoelectric material has high impedance compared to the magnetostrictive material. When a magnetostrictive material is used, power generation by resonant vibration becomes possible. When a magnetostrictive material is used, power generation is possible even in a wide temperature use range (for example, −100° C. to 100° C.).

The technical scope of the invention is not limited to the foregoing embodiment, and changes may be appropriately made without departing from the scope of the invention.

For example, although in the foregoing embodiment, a configuration in which the electric wire 214a of the coil portion 214 is wound around the linear member 212c of the vibrating portion 212 has been described as an example, the invention is not limited thereto.

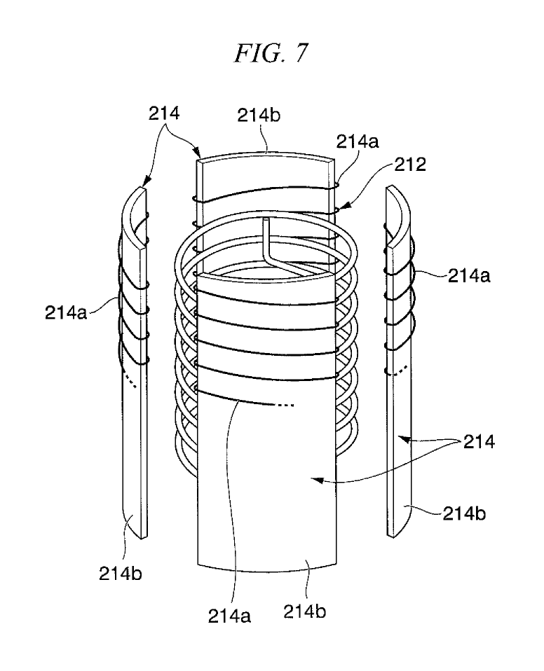

For example, as shown in FIG. 7, the coil portion 214 may be arranged so as to surround the periphery of the vibrating portion 212. In this case, a plurality of coil portions 214 are provided around the vibrating portion 212, and in each coil portion 214, an electric wire 214a is wound around a core portion 214b. In this case, as in the foregoing embodiment, reduction in size is possible. In this case, if the coil portion 214 is used as a weight body, and vibration is transmitted to the vibrating portion 212, further reduction in size becomes possible.

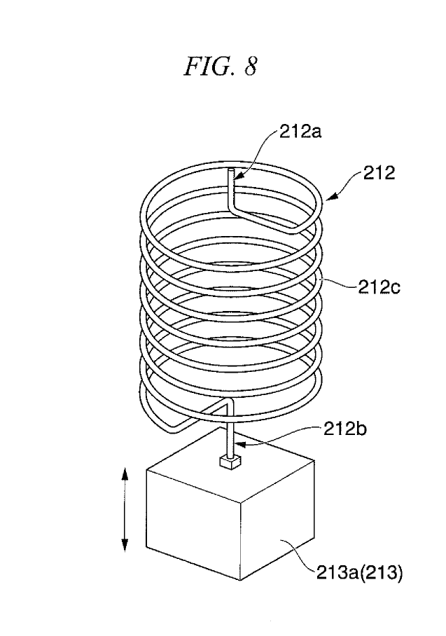

For example, although in the foregoing embodiment, a configuration in which the movable portion 213b is attached to the second end portion 212b of the vibrating portion 212, and the weight body 213a is connected to the second end portion 212b through the movable portion 213b has been described as an example, the invention is not limited thereto. For example, as shown in FIG. 8, the weight body 213a may be directly attached to the second end portion 212b of the vibrating portion 212. In this case, as in the foregoing embodiment, reduction in size becomes possible.

Although in the foregoing embodiment, a configuration in which an induced current generated by the power-generating unit 210 according to the vibration of the electronic device 2 is supplied to the power supply unit 220 each time has been described as an example, the invention is not limited thereto. For example, a vibration storage portion which stores force (elastic energy) for causing the vibrating portion 212 to vibrate may be provided.

In this configuration, the movable portion 213b can be moved by force stored in the vibration storage portion, and the vibrating portion 212 can vibrate through the movable portion 213b. For this reason, continuous power generation becomes possible even when the electronic device 2 is not vibrating. As the vibration storage portion, for example, a spring mechanism or the like may be used.

Although in the foregoing embodiment, a configuration in which the weight body 213a and the movable portion 213b are provided as the vibration transmission portion 213 has been described as an example, the invention is not limited thereto. For example, a resonance structure or the like may be attached to the power-generating unit 210. Therefore, it is possible to efficiently vibrate the vibrating portion 212.

For example, although in the foregoing embodiments, a form in which the weight body 213a or the weight body 214 is provided outside the vibrating portion 212 has been described, the invention is not limited thereto. For example, the shape of the coil may be used, and the weight body 213a or the weight body 214 may be formed inside the vibrating portion 212. Therefore, it becomes possible to achieve further reduction in size.

What is claimed is:

1. A power generator comprising:
a spring; and
a power-generating unit which is formed using a magnetostrictive material;
wherein the power-generating unit generates power by force stored in the spring when force is not applied to the magnetostrictive material.

2. The power generator according to claim 1,
wherein the spring stores force by vibration, operation of an operator, or wind power.

3. An electronic device comprising:
the power generator according to claim 1.

4. A power-generating device comprising:
a vibrating portion which is formed to have a spiral shape in one direction and comprises the magnetostrictive material;
a vibration transmission portion which transmits vibration to the vibrating portion; and
a coil portion which generates an induced current according to change in magnetic flux density caused by the vibration of the vibrating portion.

5. The power-generating device according to claim 4,
wherein the vibration transmission portion is provided integrally with the vibrating portion.

6. The power-generating device according to claim 4,
wherein a first end portion of the vibrating portion in the one direction is fixed.

7. The power-generating device according to claim 6,
wherein the vibration transmission portion has a weight body which is connected to a second end portion different from the first end portion of the vibrating portion in the one direction.

8. The power-generating device according to claim 7,
wherein the weight body is attached to the second end portion.

9. The power-generating device according to claim 7,
wherein the vibration transmission portion has a movable portion which is connected to the second end portion, and
the weight body is attached to the movable portion.

10. The power-generating device according to claim 9, further comprising:
a frame portion which has a fixed portion fixing the first end portion,
wherein the movable portion is movably fixed to the frame portion.

11. The power-generating device according to claim 4,
wherein a weight body is formed inside the coil portion.

12. The power-generating device according to claim 4,
wherein the coil portion is wound around the vibrating portion.

13. An electronic device comprising:
a processing unit which performs predetermined processing;
a power supply unit which supplies power to the processing unit; and
a power-generating unit which generates at least a part of the power to be supplied from the power supply unit to the processing unit,
wherein the power-generating device according to claim 4 is used as the power-generating unit.
